(19) United States
(12) Patent Application Publication
(10) Pub. No.: US 2007/0001555 A1
(43) Pub. Date: Jan. 4, 2007

(54) QUARTZ RESONATOR REED, QUARTZ RESONATOR, AND QUARTZ OSCILLATOR

(75) Inventors: Masako TANAKA, Suwa-shi, Nagano-ken (JP); Susumu MAEDA, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/425,046

(22) Filed: Jun. 19, 2006

(30) Foreign Application Priority Data
Jun. 29, 2005 (JP) 2005-189511

(51) Int. Cl. H01L 41/18

(52) U.S. Cl. 310/361

(57) ABSTRACT

A quartz resonator blank vibrating at a predetermined resonance frequency with driving power applied to at least a principal surface, wherein, defining the electrical axis, the mechanical axis, and the optical axis of quartz as X-axis, Y-axis, and Z-axis, respectively, the principal surface includes a side parallel to an X′-axis defined by rotating the X-axis clockwise around the Z-axis as an angle φ no smaller than 7 degrees and no greater than 17.3 degrees, and a side parallel to a Z′-axis defined by rotating the Z-axis clockwise around the X′-axis as an angle θ no smaller than 34.3 degrees and no greater than 35.25 degrees.

### BACKGROUND OF THE INVENTION

1. Technical Field

The present invention relates to a double-rotation-cut quartz resonator blank having a thickness shear vibration mode as a principal vibration mode and having a cut surface inclined around two crystal axes of quartz crystal, a quartz resonator and a quartz oscillator each using the double-rotation-cut quartz resonator blank.

2. Related Art

In general, for a piezoelectric device such as a resonator or an oscillator used for an electronic apparatus such as a communication apparatus, information apparatus, or a household appliance, quartz crystal is adopted as a piezoelectric material because it can provide a stable frequency characteristic. A quartz resonator blank is formed using a quartz plate carved out from the quartz crystal with a predetermined angle. In particular, an AT-cut quartz plate has been used for a quartz resonator blank since a long time ago because it can provide a stable frequency in a wide temperature range. As shown in FIG. 12, the AT-cut quartz plate has a side parallel to the X-axis of the crystal axes of the quartz crystal and is carved out therefrom with a cutting angle of rotating the X-Z plane around the X-axis clockwise (taking the case of viewing the +X area from the −X area in the X-axis as a reference) as much as 35 degrees and 15 minutes. This cutting method is called single-rotation-cut. It has been known that a quartz resonator blank using the AT-cut quartz plate changes in the frequency according to temperature variation, in other words, in so called frequency temperature behavior, the frequency variation becomes large in a high-temperature range around 100° C. (e.g., JP-A-5-235678). In order for improving the frequency temperature behavior in the high temperature range, a quartz plate carved out in a plane, which is obtained by rotating one of the crystal axes of the quartz crystal to define a new axis and then rotating another of the crystal axes around the new axis, is proposed (e.g.. JP-A-2004-7420). This cutting method is called double-rotation (twice rotated) -cut.

However, the characteristic of the quartz resonator blank has drive level dependency, such as varying the resonance frequency by applying electric driving power for exciting the quartz resonator blank (hereinafter referred to as driving power), besides the frequency temperature behavior described above. Hereinafter, an amount of the resonance frequency variation caused by the drive level dependency is referred to as DLD.

The DLD will be explained in detail with reference to FIG. 13. FIG. 13 is a chart showing the relation between the driving power and the amount of the resonance frequency variation, namely the DLD. FIG. 13 shows approximated lines respectively representing the DLDs each corresponding to the resonance frequency and the size (chip size) of the principal surface of the resonator blank. Conditions of the respective approximated lines will be described below.
(a) Resonance frequency: 48 MHz, chip size: 2.0 mm×1.2 mm
(b) Resonance frequency: 40 MHz, chip size: 2.0 mm×1.1 mm
(c) Resonance frequency: 40 MHz, chip size: 4.0 mm×2.2 mm
(d) Resonance frequency: 20 MHz, chip size: 5.4 mm×1.6 mm

As shown in FIG. 13, the DLDs are in approximate proportion to the driving power, the greater the driving power becomes, the larger the amount of frequency variation becomes. Further, as understood from the comparison of the lines (b) and (c) shown in FIG. 13, in the DLDs with the same resonance frequencies, the smaller the area of the principal surface is, the greater the amount of frequency variation is. Further, as understood from the comparison between the lines (a), (b), and (d), the higher the resonance frequency is, the greater the amount of frequency variation is. Therefore, in the conventional quartz resonator blank described in JP-A-2004-7420, in the case in which the quartz resonator blank is formed to have a high resonance frequency or the small principal surface area, the DLD thereof becomes large, and the amount of frequency variation may problematically exceed the allowable level.

### SUMMARY

The invention addresses the above problem, and has an advantage of reducing the DLD to make it possible to provide a small sized quartz resonator blank requiring greater driving power, a quartz resonator and a quartz oscillator equipped with the quartz resonator blank.

In order for solving the problems, the inventors conducted various researches and experiments regarding the cutting angle of quartz crystal and found the cutting angle offering a small DLD in the small sized quartz resonator blank requiring greater driving power. The invention is made based on this knowledge.

In a quartz resonator blank according to an aspect of the invention vibrates at a predetermined resonance frequency with driving power applied to at least a principal surface, the electrical-axis, the mechanical-axis, and the optical-axis of quartz are defined as X-axis, Y-axis, and Z-axis, respectively, and the principal surface includes a side parallel to an X′-axis defined by rotating the X-axis clockwise around the Z-axis as an angle φ no smaller than 7 degrees and no greater than 17.3 degrees, and a side parallel to a Z′-axis defined by rotating the Z-axis clockwise around the X′-axis as an angle θ no smaller than 34.3 degrees and no greater than 35.25 degrees.

According to the quartz resonator blank of this aspect of the invention, the DLD can be reduced by using the double-rotation-cut in which the X-axis and the Z-axis are rotated as predetermined angles. Namely, the DLD can be suppressed to a small value even in the quartz resonator blank requiring great driving power (excitation level), and accordingly, a quartz resonator blank with high frequency accuracy (high quality) can be provided.

Further, the resonance frequency is no lower than 48 MHz and no higher than 100 MHz, and the area of the principal surface is preferably no smaller than 4.0 mm² and no larger than 8.0 mm².

By thus configured, even if the quartz resonator blank with a resonance frequency of no lower than 48 MHz and no higher than 100 MHz, and the area of the principal surface of no smaller than 4.0 mm² and no larger than 8.0 mm² is resonated with the driving power of about 500 μW, the DLD) can be suppressed to no greater than 5 ppm.

Further, the resonance frequency is no lower than 27 MHz and no higher than 48 MHz, the principal surface includes a side parallel to an X′-axis defined by rotating the X-axis clockwise around the Z-axis as an angle φ no smaller than 8 degrees and no greater than 16 degrees, and a side parallel to a Z′-axis defined by rotating the Z-axis clockwise around the X′axis as an angle θ no smaller than 34.3 degrees and no greater than 35.25 degrees, and the area of the principal surface is preferably no smaller than 1.4 mm² and no larger than 2.0 mm².

By thus configured, even if the quartz resonator blank with a resonance frequency of no lower than 27 MHz and no higher than 48 MHz, and the area of the principal surface of no smaller than 1.4 mm² and no larger than 2.0 mm² is resonated with the driving power of about 500 μW, the DLD can be suppressed to no greater than 5 ppm.

Further, the resonance frequency is no lower than 27 MHz and no higher than 48 MHz, the principal surface includes a side parallel to an X′-axis defined by rotating the X-axis clockwise around the Z-axis as an angle φ no smaller than 10 degrees and no greater than 14 degrees, and a side parallel to a Z′-axis defined by rotating the Z-axis clockwise around the X′-axis as an angle φ no smaller than 34.3 degrees and no greater than 35.25 degrees, and the area of the principal surface is preferably no smaller than 0.8 mm² and no larger than 1.4 mm².

By thus configured, even if the quartz resonator blank with a resonance frequency of no lower than 27 MHz and no higher than 48 MHz, and the area of the principal surface of no smaller than 0.8 mm² and no larger than 1.4 mm² is resonated with the driving power of about 500 μW, the DLD can be suppressed to no greater than 5 ppm.

Further, the resonance frequency is no lower than 48 MHz and no higher than 100 MHz, the principal surface includes a side parallel to an X′-axis defined by rotating the X-axis clockwise around the Z-axis as an angle φ no smaller than 8 degrees and no greater than 16 degrees, and a side parallel to a Z′-axis defined by rotating the Z-axis clockwise around the X′-axis as an angle θ no smaller than 34.3 degrees and no greater than 35.25 degrees, and the area of the principal surface is preferably no smaller than 2.0 mm² and no larger than 4.0 mm².

By thus configured, even if the quartz resonator blank with a resonance frequency of no lower than 48 MHz and no higher than 100 MHz, and the area of the principal surface of no smaller than 2.0 mm² and no larger than 4.0 mm² is resonated with the driving power of about 500 μW, the DLD can be suppressed to no greater than 5 ppm.

Further, the resonance frequency is no lower than 48 MHz and no higher than 100 MHz, the principal surface includes a side parallel to an X′-axis defined by rotating the X-axis clockwise around the Z-axis as an angle φ no smaller than 9 degrees and no greater than 15.5 degrees, and a side parallel to a Z′-axis defined by rotating the Z-axis clockwise around the X′-axis as an angle θ no smaller than 34.3 degrees and no greater than 35.25 degrees, and the area of the principal surface is preferably no smaller than 1.4 mm² and no larger than 2.0 mm².

By thus configured, even if the quartz resonator blank with a resonance frequency of no lower than 48 MHz and no higher than 100 MHz, and the area of the principal surface of no smaller than 1.4 mm² and no larger than 2.0 mm² is resonated with the driving power of about 500 μW, the DLD can be suppressed to no greater than 5 ppm.

Further, the angle φ is preferably no smaller than 11.5 degrees and no greater than 12.5 degrees.

By thus configured, the DLD can be suppressed to a further small value. Namely it becomes possible to provide the quartz resonator blank capable of suppressing the variation of the DLD to as small as no greater than 2.5 ppm even if it has a resonance frequency of no lower than 27 MHz and no higher than 100 MHz, and the area of the principal surface of no smaller than 0.8 mm² and no larger than 4.0 mm², and is resonated with the driving power of about 500 μW.

Further, a quartz resonator according to another aspect of the invention includes a package, and the quartz resonator blank described above housed in the package.

According to the quartz resonator of this aspect of the invention, the DLD can be suppressed to a small value by using the double-rotation-cut quartz resonator blank described above housed in the package. Namely, the frequency variation caused by the DLD can be suppressed to a small value even in the quartz resonator requiring great driving power (excitation level), and accordingly, a quartz resonator with high frequency accuracy (high quality) can be provided.

Further, a quartz oscillator according to still another aspect of the invention includes the quartz resonator blank described above, and a circuit section having at least a function of driving the quartz resonator blank.

According to the quartz oscillator of this aspect of the invention, the DLD can be suppressed to a small value by using the double-rotation-cut quartz resonator blank described above. Namely, even if great driving power (excitation level) is required, the DLD can be suppressed to a small value. Further, since the quartz resonator blank and the circuit section are provided, the connection therebetween can be shortened, thus a further small-sized quartz oscillator can be provided. Accordingly, a small-sized quartz oscillator with high frequency accuracy (high quality) can be provided.

### BRIEF DESCRIPTION OF THE DRAWINGS

The invention will now be described with reference to the accompanying drawings, wherein like numbers refer to like elements.

FIG. 1 is a schematic view of a double-rotation-cut quartz plate according to a first embodiment of the invention.

FIG. 2 is a perspective view showing a quartz resonator blank carved out from the quartz plate shown in FIG. 1.

FIG. 3 is a chart showing the relation between the excitation level and the frequency deviation in the quartz resonator blank according to a first specific example.

FIG. 4 is a chart showing the relation between the excitation level and the frequency deviation in the quartz resonator blank according to a second specific example.

FIG. 5 is a chart showing the relation between the excitation level and the frequency deviation in the quartz resonator blank according to a third specific example.

FIG. 6 is a chart showing the relation between the excitation level and the frequency deviation in the quartz resonator blank according to a fourth specific example.

FIG. 7 is a chart showing the relation between the excitation level and the frequency deviation in the quartz resonator blank according to a fifth specific example.

Fig. 8 is a plan view with a part of a lid member removed, schematically showing a quartz resonator according to a second embodiment of the invention.

FIG. 9 is a right cross-sectional view schematically showing the quartz resonator according to the invention.

FIG. 10 is a plan view with a part of a lid member removed, schematically showing a quartz oscillator according to a third embodiment of the invention.

FIG. 11 is a right cross-sectional view schematically showing the quartz oscillator according to the invention.

FIG. 12 is a schematic view of a conventional single-rotation-cut quartz plate.

FIG. 13 is a chart for explaining DLD.

### DESCRIPTION OF THE EMBODIMENTS

The best mode of each of a quartz resonator blank, a quartz resonator, and a quartz oscillator according to the invention will now be explained with reference to the drawings.

First Embodiment

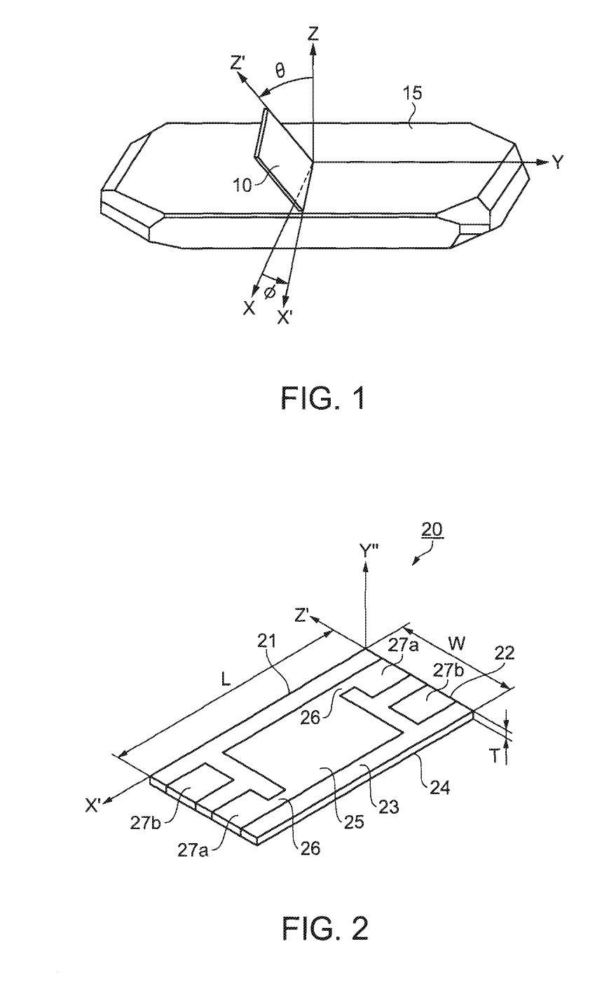

The quartz resonator blank according to the invention will be explained using FIGS. 1 and 2. FIG. 1 schematically shows a double-rotation-cut quartz plate according to a first embodiment. FIG. 2 is a perspective view showing a quartz resonator blank carved out from the quartz plate shown in FIG. 1.

As shown in FIG. 1, the three crystal axes of quartz crystal perpendicular to each other are defined as follows. Namely, the electrical axis is defined as X-axis, the mechanical axis perpendicular thereto is defined as Y-axis, and the optical axis perpendicular to both the X-axis and the Y-axis is defined as Z-axis. A quartz plate (also referred to as a quartz substrate) 10 for obtaining the quartz resonator blank according to the invention first includes a side parallel to an X′-axis, which is defined by rotating the X-axis clockwise (taking the case of viewing the +Z area from the −Z area in the Z-axis as a reference) around the Z-axis of a piece of rough crystal 15 as much as a desired angle φ in a range of no smaller than 6.5 degrees and no greater than 17.5 degrees. Further, the quartz plate 10 includes a side parallel to a Z′-axis, which is defined by rotating the Z-axis clockwise (taking the case of viewing the +X′ area from the −X′ area in the X′-axis as a reference) around the X′-axis as much as a desired angle θ in a range of no smaller than 34.3 degrees and no greater than 35.25 degrees. And, by carving out with a plane including these sides as the principal surface, the so-called double-rotation-cut quartz plate 10 is formed. Further, the quartz plate 10 is processed with a polishing process on the both surfaces to have a desired thickness and surface conditions, and then divided into small pieces by a cutting machine or the like, thus a quartz resonator blank 20 having a desired size and a desired shape as shown in FIG. 2 is carved out. Note that, the Y-axis is also rotated twice at the same time, which is not shown in FIG. 1. FIG. 2 illustrates the axis in the thickness direction of the quartz resonator blank thus carved out therefrom as a Y″-axis denoting that the Y-axis is rotated twice.

The quartz resonator blank 20 will be explained in detail. The quartz resonator blank 20 shown in FIG. 2 has rectangular principal surfaces 23, 24 each having a long side 21 with a length of L parallel to the X′-axis and a short side with a length W parallel to the Z′-axis. The principal surfaces 23, 24 are formed on the both sides with a thickness of T therebetween in a direction parallel to the Y″-axis. Note that the thickness T is inversely proportional to the resonance frequency of the quartz resonator blank 20, and the thinner the thickness of the quartz resonator blank is, the higher the resonance frequency is. In a central area of each of the principal surfaces 23, 24, there is formed an excitation electrode 25. The excitation electrode 25 formed on the right principal surface 23 is connected to external connection electrodes 27a via respective leading electrodes 26. Note that external connection electrodes 27b on the other side pass on the side surfaces of the quartz resonator blank 20 to be connected to the external connection electrodes, the leading electrodes, and the excitation electrode on the reverse surface. The quartz resonator blank 20 oscillates in a predetermined frequency in response to application of the driving power to the excitation electrodes 23, 24 on both surfaces from an oscillation circuit not shown. Note that the amount of the driving power may sometimes be referred to as an excitation level or a driving level.

As described in the related art section, the quartz resonator blank is varied in the resonance frequency in accordance with the amount of the driving power. The inventors of the invention carved out the quartz plate 10 while changing stepwise the rotation angle φ of the X-axis around the Z-axis to manufacture the double-rotation-cut quartz resonator blank 20 with thickness shear vibration mode according to the invention by way of trial. Note that, in the present trial, attention was focused on the quartz resonator blank 20, which was small-sized (a quartz resonator blank with the small principal surface area), for high frequency band, and accordingly required a relatively large amount of driving power.

Further, the resonance frequency of each of the sample quartz resonator blanks 20 was measured while changing the driving power (excitation level) stepwise at room temperature. As a result, it was found that the quartz resonator blank 20 with the DLD having no practical problems can be formed by setting the resonance frequency, the angle φ, the angle θ, and the area of the principal surface. In particular, it was found that the quartz resonator blank 20 carved out with the angle φ in a range of no smaller than 11.5 degrees and no greater than 12.5 degrees could offer remarkably small DLD. Note here that the amount of frequency variation with no practical problems, which is required generally, denotes the DLD of no greater than 5 ppm in applying the driving power of up to about 500 μW to the quartz resonator blank 20.

According to the quartz resonator blank 20 of the present embodiment, the DLD can be reduced. In detail, the quartz resonator blank 20, which is capable of suppressing the amount of frequency variation, namely the DLD, to no greater than 5 ppm in applying the driving power of up to about 500 μW, can be provided. As described above, the quartz resonator blank 20, which has the small DLD and offers high frequency accuracy (high quality) even with a large amount of required driving power, can be provided.

Further, in the quartz resonator blank carved out with the angle φ in a range of no smaller than 11.5 degrees and no greater than 12.5 degrees, the DLD in applying the driving power of up to about 500 μW can further be reduced. Specifically, the DLD can be reduced to no greater than 2.5 ppm.

Note that, although the quartz resonator blank is explained with the rectangular shape in the first embodiment described above, the shape of the quartz resonator blank is not limited thereto. The quartz resonator blank with a shape of, for example, a circle or a square can offer the same advantage.

First Specific Example

The quartz plate was carved out while changing stepwise the rotation angle φ of the X-axis to manufacture the quartz resonator blanks with resonance frequencies in the thickness shear vibration mode of 48 MHz and 100 MHz, respectively, by way of trial. Each of the quartz resonator blanks of the respective resonance frequencies was arranged to have a chip size of 3 mm×1.5 mm (described as the size of L×W shown in FIG. 2), namely the principal surface area of 4.5 mm². Further, in the first specific example, the angle θ was fixed to 35 degrees. Note that, as a comparative example, a conventional single-rotation-cut quartz resonator blank having the same resonance frequency, the same chip size, and the angle φ of zero degree was also manufactured by way of trial. And, measurement of the amount of frequency variation (frequency deviation ΔF (ppm)) in the quartz resonator blank of the first specific example was conducted while sweeping the excitation level up to about 700 μW.

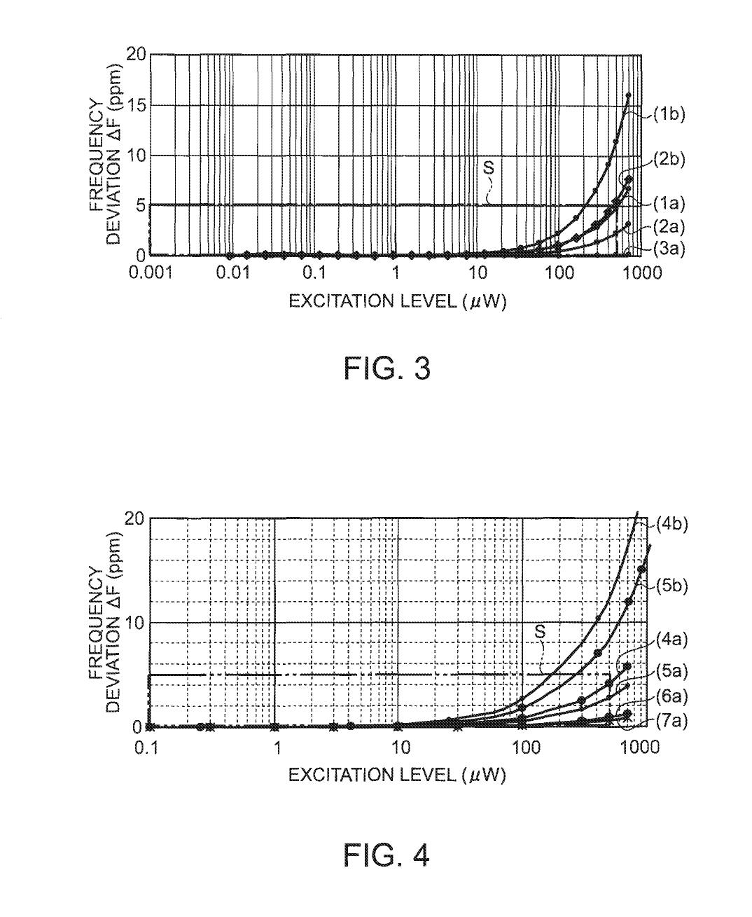

The results are shown in FIG. 3. FIG. 3 is a chart showing the relation between the excitation level and the frequency deviation of the quartz resonator of the first specific example, wherein the vertical axis represents the frequency deviation and the horizontal axis represents the excitation level (μW). Note that a logarithmic scale is used for the horizontal axis. The curves in the chart shown in FIG. 3 respectively represent DLDs of the following quartz resonator blanks:
(1a) the quartz resonator blank in the first specific example with the resonance frequency of 100 MHz, the angle φ of 7 degrees and 17.3 degrees;
(2a) the quartz resonator blank in the first specific example with the resonance frequency of 48 MHz, the angle φ of 7 degrees and 17.3 degrees;
(3a) the quartz resonator blank in the first specific example with the resonance frequency of 48 MHz and 100 MHz, the angle φ of 12 degrees;
(1b) the quartz resonator blank with the resonance frequency of 100 MHz, and the angle φ of zero degree (a comparative example); and
(2b) the quartz resonator blank with the resonance frequency of 48 MHz, and the angle φ of zero degree (a comparative example).

As shown in FIG. 3, the DLD of the quartz resonator blank gradually increases form around an area exceeding 10 μW, and shows large variation in an area exceeding 100 μW. The curves (1a), (2a), and (3a) of the quartz resonator blanks according to the first specific example show dramatic decrease in each of the resonance frequencies in comparison with the single-rotation-cut quartz resonator blanks illustrated with the curves (1b) and (2b) as the comparative examples. In general, the DLD is required to be no greater than 5 ppm in the excitation level of 500 μW. The double-dashed line in the drawing illustrates a range where the DLD stays no greater than 5 ppm with the excitation level of no greater than 500 μW. As shown in FIG. 3, the quartz resonator blanks according to the first specific example illustrated with the curves (1a), (2a), and (3a) could suppress the DLD to no greater than 5 ppm even in the excitation level of 500 μW.

Further detailed explanations will be presented taking the quarts resonator blank with the resonance frequency of 100 MHz as an example. The curve (1a) illustrates the DLD with the angle φ of 7 degrees and 17.3 degrees. The DLD in this case is approximately 5 ppm in the excitation level of 500 μW. If the angle φ becomes greater than 7 degrees, the curve gradually becomes gentler in the slant and the rising portion. And, the curve (3a) with the angle φ of 12 degrees makes about the lower limit, and with larger angle φ, the curve gradually becomes steep again in the slant and the rising portion of the quadratic curve, and with the angle φ of 17.3 degrees, the curve roughly overlaps the curve (1a) with the angle φ of 7 degrees. Namely, the quartz resonator blank carved out with the angle φ in a range from 7 degrees to 17.3 degrees has the DLD curve in an area between the curve (1a) and the curve (3a). Therefore, it is obvious that the quartz resonator blank carved out with the angle φ in a range from 7 degrees to 17.3 degrees has the DLD in a range of no greater than 5 ppm. Further, although not shown in the drawings, similar trial manufacture was conducted while changing the area of the principal surface stepwise. As a result, an equivalent effect could be confirmed with the area of the principal surface in a range of no smaller than 4.0 mm² and no greater than 8 mm₂.

Further, similarly to the above, in the quartz resonator blank of 48 MHz, the DLD can be suppressed to no greater than 5 ppm with the curve existing in a range between the curve (2a) and the curve (3a). Note that the curve (3a) also represents the curve of the 48 MHz quartz resonator blank with the angle φ of 12 degrees.

According to the above results, in the resonance frequency band of no lower than 48 MHz and no higher than 100 MHz, the double-rotation-cut quartz resonator blank with the principal surface area of no smaller than 4.0 mm² and no larger than 8 mm² carved out with the angle φ of no smaller than 7 degrees and no greater than 17.3 degrees can suppress the DLD in the excitation level of 500 μW to no greater than 5 ppm.

Further, in the curve (3a), the DLD is hardly observed, namely no greater than 1 ppm, even in the excitation level of 700 μW. As described above, by setting the angle φ to a value around 12 degrees (e.g., from 11.5 degrees to 12.5 degrees), the quartz resonator blank with the extremely small DLD can also be provided.

Second Specific Example

Trial manufacture was further conducted similarly to the first specific example with different resonance frequencies and chip sizes. In the second specific example, the quartz resonator blanks according to the invention with the resonance frequencies in the thickness shear vibration mode of 27 MHz and 48 MHz, respectively, are manufactured by way of trial. Each of the quartz resonator blanks of the respective resonance frequencies was arranged to have a chip size of 1.4 mm×1.0 mm (described as the size of L×W shown in FIG. 2), namely the principal surface area of 1.4 mm². Further, also in the second specific example, the angle θ was fixed to 35 degrees. And, measurement of the amount of frequency variation (frequency deviation ΔF (ppm)) in the quartz resonator blank of the second specific example was conducted while sweeping the excitation level up to about 700 μW.

The results are shown in FIG. 4. FIG. 4 is a chart showing the relation between the excitation level and the frequency deviation of the quartz resonator of the second specific example, wherein the vertical axis represents the frequency deviation and the horizontal axis represents the excitation level (μW). Note that a logarithmic scale is used for the horizontal axis. The curves in the chart shown in FIG. 4 respectively represent DLDs of the following quartz resonator blanks:
(4a) the quartz resonator blank in the second specific example with the resonance frequency of 48 MHz, the angle φ of 8 degrees and 16 degrees;
(5a) the quartz resonator blank in the second specific example with the resonance frequency of 27 MHz, the angle φ of 8 degrees and 16 degrees;
(6a) the quartz resonator blank in the second specific example with the resonance frequency of 48 MHz, the angle φ of 12 degrees;
(7a) the quartz resonator blank in the second specific example with the resonance frequency of 27 MHz, the angle φ of 12 degrees;
(4b) the quartz resonator blank with the resonance frequency of 48 MHz, and the angle φ of zero degree (a comparative example); and
(5b) the quartz resonator blank with the resonance frequency of 27 MHz. and the angle φ of zero degree (a comparative example).

Similarly to the first specific example, the curves (4a), (5a), (6a), and (7a) of the quartz resonator blanks according to the second specific example show dramatic decrease in each of the resonance frequencies in comparison with the single-rotation-cut quartz resonator blanks illustrated with the curves (4b) and (5b) as the comparative examples. And, as shown in FIG. 4, the quartz resonator blanks according to the second specific example illustrated with the curves (4a), (5a), (6a), and (7a) could suppress the DLD to no greater than 5 ppm even in the excitation level of 500 μW. Further, although not shown in the drawings, similar trial manufacture was conducted while changing the area of the principal surface stepwise. As a result, an equivalent effect could be confirmed with the area of the principal surface in a range of no smaller than 1.4 mm² and no greater than 2.0 mm². Note that the description regarding the same events as in the first specific example will be omitted here.

Accordingly, in the resonance frequency band of no lower than 27 MHz and no higher than 48 MHz, the double-rotation-cut quartz resonator blank with the principal surface area of no smaller than 1.4 mm² and no larger than 2.0 mm² carved out with the angle φ of no smaller than 8 degrees and no greater than 16 degrees can suppress the DLD in the excitation level of 500 μW to no greater than 5 ppm.

Third Specific Example

Trial manufacture was further conducted similarly to the first specific example with different resonance frequencies and chip sizes. In the third specific example, the quartz resonator blanks according to the invention with the resonance frequencies in the thickness shear vibration mode of 27 MHz and 48 MHz, respectively, are manufactured by way of trial. Each of the quartz resonator blanks of the respective resonance frequencies was arranged to have a chip size of 1.0 mm×0.8 mm (described as the size of L×W shown in FIG. 2), namely the principal surface area of 0.8 mm². Further, also in the third specific example, the angle θ was fixed to 35 degrees. And, measurement of the amount of frequency variation (frequency deviation ΔF (ppm)) in the quartz resonator blank of the third specific example was conducted while sweeping the excitation level up to about 700 μW.

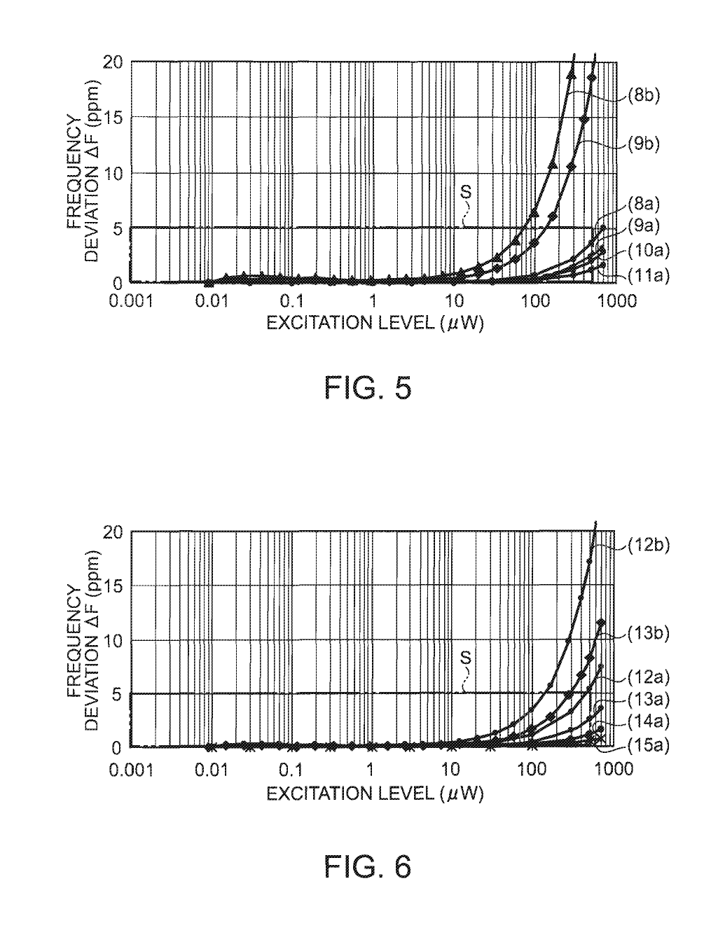

The results are shown in FIG. 5. FIG. 5 is a chart showing the relation between the excitation level and the frequency deviation of the quartz resonator of the third specific example, wherein the vertical axis represents the frequency deviation and the horizontal axis represents the excitation level (μW). Note that a logarithmic scale is used for the horizontal axis. The curves in the chart shown in FIG. 5 respectively represent DLDs of the following quartz resonator blanks:
(8a) the quartz resonator blank in the third specific example with the resonance frequency of 48 MHz, the angle φ of 10 degrees and 14 degrees;
(9a) the quartz resonator blank in the third specific example with the resonance frequency of 27 MHz, the angle φ of 10 degrees and 14 degrees;
(10a) the quartz resonator blank in the third specific example with the resonance frequency of 48 MHz, the angle φ of 12 degrees;
(11a) the quartz resonator blank in the third specific example with the resonance frequency of 27 MHz, the angle φ of 12 degrees;
(8b) the quartz resonator blank with the resonance frequency of 48 MHz, and the angle φ of zero degree (a comparative example); and
(9b) the quartz resonator blank with the resonance frequency of 27 MHz, and the angle φ of zero degree (a comparative example).

Similarly to the first specific example, the curves (8a), (9a), (10a), and (11a) of the quartz resonator blanks according to the third specific example show dramatic decrease in each of the resonance frequencies in comparison with the single-rotation-cut quartz resonator blanks illustrated with the curves (8b) and (9b) as the comparative examples. And, as shown in FIG. 5, the quartz resonator blanks according to the third specific example illustrated with the curves (8a), (9a), (10a), and (11a) could suppress the DLD to no greater than 5 ppm even in the excitation level of 500 μW. Further, although not shown in the drawings, similar trial manufacture was conducted while changing the area of the principal surface stepwise. As a result, an equivalent effect could be confirmed with the area of the principal surface in a range of no smaller than 8.0 mm² and no greater than 1.4 mm². Note that the description regarding the same events as in the first specific example will be omitted here.

Accordingly, in the resonance frequency band of no lower than 27 MHz and no higher than 48 MHz, the double-rotation-cut quartz resonator blank with the principal surface area of no smaller than 0.8 mm² and no larger than 1.4 mm² carved out with the angle φ of no smaller than 10 degrees and no greater than 14 degrees can suppress the DLD in the excitation level of 500 μW to no greater than 5 ppm.

Fourth Specific Example

Trial manufacture was further conducted similarly to the first specific example with different resonance frequencies and chip sizes. In the fourth specific example, the quartz resonator blanks according to the invention with the resonance frequencies in the thickness shear vibration mode of 48 MHz and 100 MHz, respectively, are manufactured by way of trial. Each of the quartz resonator blanks of the respective resonance frequencies was arranged to have a chip size of 2.0 mm×1.0 mm (described as the size of L×W shown in FIG. 2), namely the principal surface area of 2.0 mm². Further, also in the fourth specific example, the angle θ was fixed to 35 degrees. And, measurement of the amount of frequency variation (frequency deviation ΔF (ppm)) in the quartz resonator blank of the fourth specific example was conducted while sweeping the excitation level up to about 700 μW.

The results are shown in FIG. 6. FIG. 6 is a chart showing the relation between the excitation level and the frequency deviation of the quartz resonator of the fourth specific example, wherein the vertical axis represents the frequency deviation and the horizontal axis represents the excitation level (μW). Note that a logarithmic scale is used for the horizontal axis. The curves in the chart shown in FIG. 6 respectively represent DLDs of the following quartz resonator blanks:
(12a) the quartz resonator blank in the fourth specific example with the resonance frequency of 100 MHz, the angle φ of 8 degrees and 16 degrees;
(13a) the quartz resonator blank in the fourth specific example with the resonance frequency of 48 MHz, the angle φ of 8 degrees and 16 degrees;
(14a) the quartz resonator blank in the fourth specific example with the resonance frequency of 100 MHz, the angle φ of 12 degrees;
(15a) the quartz resonator blank in the fourth specific example with the resonance frequency of 48 MHz, the angle φ of 12 degrees;
(12b) the quartz resonator blank with the resonance frequency of 100 MHz, and the angle φ of zero degree (a comparative example); and
(13b) the quartz resonator blank with the resonance frequency of 48 MHz, and the angle φ of zero degree (a comparative example).

to the first specific example, the curves (12a), (13a), (14a), and (15a) of the quartz resonator blanks according to the fourth specific example show dramatic decrease in each of the resonance frequencies in comparison with the single-rotation-cut quartz resonator blanks illustrated with the curves (12b) and (13b) as the comparative examples. And, as shown in FIG. 6, the quartz resonator blanks according to the fourth specific example illustrated with the curves (12a), (13a), (14a), and (15a) could suppress the DLD to no greater than 5 ppm even in the excitation level of 500 μW. Further, although not shown in the drawings, similar trial manufacture was conducted while changing the area of the principal surface stepwise. As a result, an equivalent effect could be confirmed with the area of the principal surface in a range of no smaller than 2.0 mm² and no greater than 4.0 mm². Note that the description regarding the same events as in the first specific example will be omitted here.

Accordingly, in the resonance frequency band of no lower than 48 MHz and no higher than 100 MHz, the double-rotation-cut quartz resonator blank with the principal surface area of no smaller than 2.0 mm² and no larger than 4.0 mm² carved out with the angle φ of no smaller than 8 degrees and no greater than 16 degrees can suppress the DLD in the excitation level of 500 μW to no greater than 5 ppm.

Fifth Specific Example

Trial manufacture was further conducted similarly to the first specific example with different resonance frequencies and chip sizes. In the fifth specific example, the quartz resonator blanks according to the invention with the resonance frequencies in the thickness shear vibration mode of 48 MHz and 100 MHz, respectively, are manufactured by way of trial. Each of the quartz resonator blanks of the respective resonance frequencies was arranged to have a chip size of 1.4 mm×1.0 mm (described as the size of L×W shown in FIG. 2), namely the principal surface area of 1.4 mm². Further, also in the fifth specific example, the angle θ was fixed to 35 degrees. And, measurement of the amount of frequency variation (frequency deviation ΔF (ppm)) in the quartz resonator blank of the fifth specific example was conducted while sweeping the excitation level up to about 700 μW.

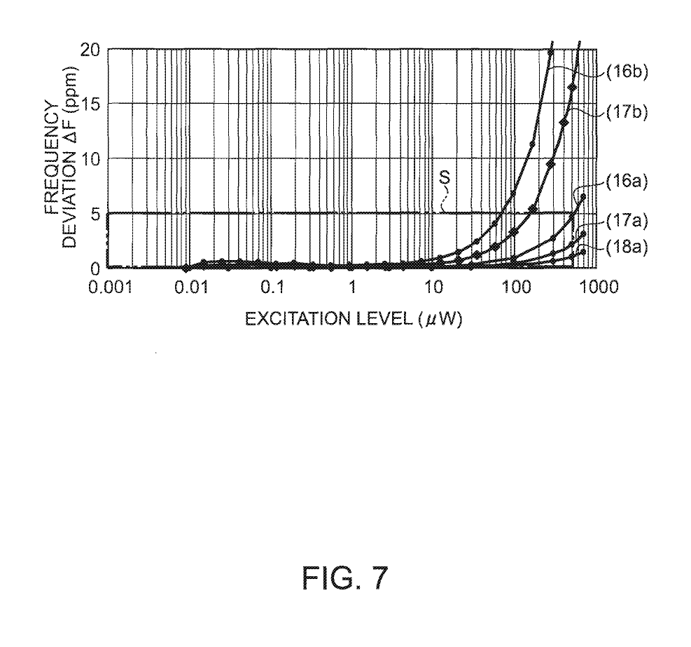

The results are shown in FIG. 7. FIG. 7 is a chart showing the relation between the excitation level and the frequency deviation of the quartz resonator of the fifth specific example, wherein the vertical axis represents the frequency deviation and the horizontal axis represents the excitation level (μW). Note that a logarithmic scale is used for the horizontal axis. The curves in the chart shown in FIG. 7 respectively represent DLDs of the following quartz resonator blanks:
(16a) the quartz resonator blank in the fifth specific example with the resonance frequency of 100 MHz, the angle φ of 9 degrees and 15.5 degrees;
(17a) the quartz resonator blank in the fifth specific example with the resonance frequency of 48 MHz, the angle φ of 9 degrees and 15.5 degrees;
(18a) the quartz resonator blank in the fifth specific example with the resonance frequency of 100 MHz and 48 MHz, the angle φ of 12 degrees;
(16b) the quartz resonator blank with the resonance frequency of 100 MHz. and the angle φ of zero degree (a comparative example); and
(17b) the quartz resonator blank with the resonance frequency of 48 MHz, and the angle φ of zero degree (a comparative example).

Similarly to the first specific example, the curves (16a), (17a), and (18a) of the quartz resonator blanks according to the fifth specific example show dramatic decrease in each of the resonance frequencies in comparison with the single-rotation-cut quartz resonator blanks illustrated with the curves (16b) and (17b) as the comparative examples. And, as shown in FIG. 7, the quartz resonator blanks according to the fifth specific example illustrated with the curves (16a), (17a), and (18a) could suppress the DLD to no greater than 5 ppm even in the excitation level of 500 μW, Further, although not shown in the drawings, similar trial manufacture was conducted while changing the area of the principal surface stepwise. As a result, an equivalent effect could be confirmed with the area of the principal surface in a range of no smaller than 1.4 mm² and no greater than 2.0 mm². Note that the description regarding the same events as in the first specific example will be omitted here.

Accordingly, in the resonance frequency band of no lower than 48 MHz and no higher than 100 MHz, the double-rotation-cut quartz resonator blank with the principal surface area of no smaller than 1.4 mm² and no larger than 2.0 mm² carved out with the angle φ of no smaller than 9 degrees and no greater than 15.5 degrees can suppress the DLD in the excitation level of 500 μW to no greater than 5 ppm.

Second Embodiment

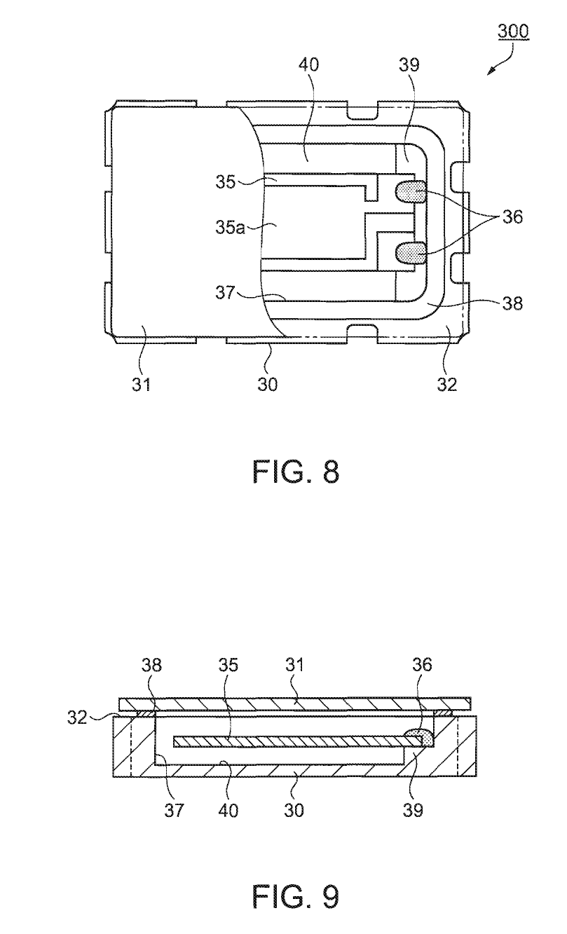

An example of a quartz resonator according to the invention will be explained as a second embodiment of the invention with reference to the drawings. FIG. 8 is a plan view with a part of a lid member eliminated, schematically showing a quartz resonator as the second embodiment of the invention. FIG. 9 is a right cross-sectional view schematically showing the quartz resonator according to the second embodiment of the invention.

As shown in FIGS. 8 and 9, the quartz resonator 300 is composed of an insulating base 30 made of, for example, ceramic as an example of a package, a lid member 31 for sealing an opening 37 of the insulating base 30, a bonding member 38 for bonding the insulating base 30 and the lid member 31, a quartz resonator blank 35, and a conductive adhesive 36 for connecting the quartz resonator blank 35 to the insulating base 30.

On the bottom section 40 of the opening 37 provided in roughly the center section of the insulating base 30, there is formed a support section 39. On the upper surface of the support section 39, there is implemented the quarts resonator blank 35, which is provided with excitation electrodes and so on, connected with a connecting member such as the conductive adhesive 36. As the quartz resonator blank 35, the double-rotation-cut quartz resonator blank 35 explained in the first embodiment described above. The conductive adhesive 36 includes silver debris or silver particles mixed in a resin base material as filler, and can be cured by a heating process, ultraviolet irradiation, and so on to also provide electrical connection.

The opening 37 of the insulating base 30 is air-tightly sealed by the lid member 31 bonded thereto via the bonding member 38 formed on the upper surface 32 of the insulating base 30. Note that the outer surface of the insulating base 30 is provided with conducting wiring section (not shown) led from the opening 37, and bonded to a mounting board or the like.

In the quartz resonator 300 according to the second embodiment described above, the double-rotation-cut quartz resonator blank 35 explained in the first embodiment is used. Therefore, the quartz resonator 300, which is capable of suppressing the amount of frequency variation, namely the DLD, to no greater than 5 ppm in applying the driving power of up to about 500 μW, can be provided.

Note that, although the quartz resonator with a configuration, in which the insulating base made of ceramic is used as the package, and the quartz resonator blank is housed in the insulating base, is explained as an example in the second embodiment, the package is not limited thereto. For example, a configuration, in which the quartz resonator blank is connected to one end of a lead wire passing through an insulating material (e.g., glass) filled in a cylindrical metallic ring, and a cylindrical cap is pressed into the metallic ring to complete sealing, can also be adopted.

Third Embodiment

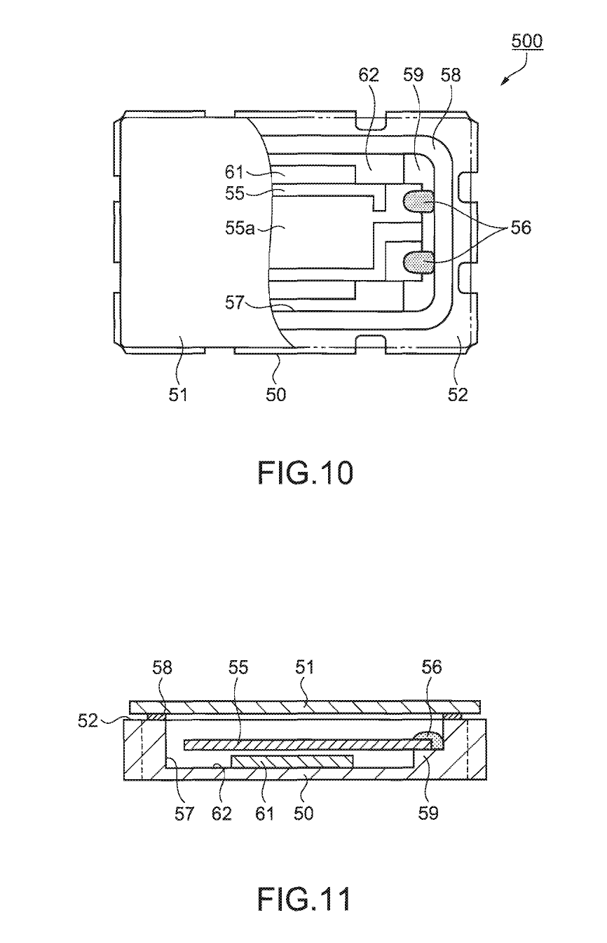

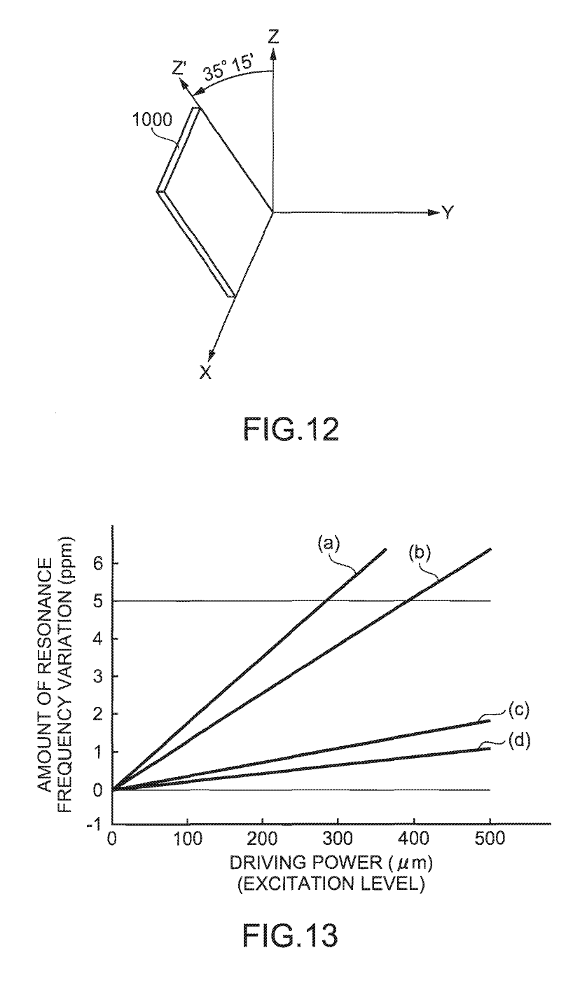

An example of a quartz oscillator according to the invention will be explained as a third embodiment of the invention with reference to the drawings. FIG. 10 is a plan view with a part of a lid member eliminated, schematically showing a quartz oscillator as the third embodiment of the invention. FIG. 11 is a right cross-sectional view schematically showing the quartz oscillator according to the third embodiment of the invention.

As shown in FIGS. 10 and 11, the quartz oscillator 500 is composed of an insulating base 50 made of, for example, ceramic, a lid member 51 for sealing an opening 57 of the insulating base 50, a bonding member 58 for bonding the insulating base 50 and the lid member 51, a quartz resonator blank 55, a conductive adhesive 56 for connecting the quartz resonator blank 55 to the insulating base 50, and a circuit element 61 as a circuit section having at least a function of oscillating the quartz resonator blank 55.

On the bottom section 62 of the opening 57 provided in roughly the center section of the insulating base 50, there is formed a support section 59. On the upper surface of the support section 59, there is implemented the quarts resonator blank 55, which is made of a quartz thin plate and provided with excitation electrodes and so on, connected with a connecting member such as the conductive adhesive 56. As the quartz resonator blank 55, the double-rotation-cut quartz resonator blank 55 is used, and it is positioned in the air except the connected section. The conductive adhesive 56 includes silver debris or silver particles mixed in a resin base material as filler, and can be cured by a heating process, ultraviolet irradiation, and so on to also provide electrical connection. On the bottom 62 of the opening 57 provided to roughly the center section of the insulating base 50, and under the quarts resonator blank 55, there is bonded, with the conductive adhesive or the like (not shown), the circuit element 61 connected to the quartz resonator blank 55 with wiring (not shown) and having at least the function of oscillating the quartz resonator blank 55. Namely, the circuit element 61 is also implemented inside the opening 57.

The opening 57 of the insulating base 50 is air-tightly sealed by the lid member 51 bonded thereto via the bonding member 58 formed on the upper surface 52 of the insulating base 50. Note that the outer surface of the insulating base 50 is provided with conducting wiring section (not shown) led from the opening 57, and bonded to a mounting board or the like.

In the quartz oscillator 500 according to the third embodiment described above, the double-rotation-cut quartz resonator blank 55 explained in the first embodiment is used. Therefore, the quartz resonator 500 capable of suppressing the DLD to no greater than 5 ppm in applying the driving power of up to about 500 μW can be provided. Further, since both of the quartz resonator blank 55 and the circuit element 61 are housed in the opening 57 of the insulating base 50, the length of the connection therebetween can be reduced to provide a further downsized quartz oscillator. Accordingly, a small-sized quartz oscillator with high frequency accuracy can be provided.

Note that, although in the third embodiment the insulating base 50 is explained taking ceramic as an example, it is not so limited. For example, a resin substrate such as an epoxy substrate or a substrate made of a metallic substrate provided with an insulating material and circuit wiring can also be used.

The entire disclosure of Japanese Patent Application No. 2005-189511, filed Jun. 29, 2005 is expressly incorporated by reference herein.

What is claimed is:

1. A quartz resonator blank vibrating at a predetermined resonance frequency with driving power applied to at least a principal surface,
wherein, defining the electrical axis, the mechanical axis, and the optical axis of quartz as X-axis, Y-axis, and Z-axis, respectively, the principal surface includes:
a side parallel to an X′-axis defined by rotating the X-axis clockwise around the Z-axis as an angle φ no smaller than 7 degrees and no greater than 17.3 degrees; and
a side parallel to a Z′-axis defined by rotating the Z-axis clockwise around the X′-axis as an angle θ no smaller than 34.3 degrees and no greater than 35.25 degrees.

2. The quartz resonator blank according to claim 1, wherein
the resonance frequency is no lower than 48 MHz and no higher than 100 MHz, and
the area of the principal surface is no smaller than 4.0 mm² and no larger than 8.0 mm².

3. The quartz resonator blank according to claim 1, wherein
the resonance frequency is no lower than 27 MHz and no higher than 48 MHz,
the angle φ is no smaller than 8 degrees and no greater than 16 degrees, and
the area of the principal surface is no smaller than 1.4 mm² and no larger than 2.0 mm².

4. The quartz resonator blank according to claim 1, wherein
the resonance frequency is no lower than 27 MHz and no higher than 48 MHz,
the angle φ is no smaller than 10 degrees and no greater than 14 degrees, and
the area of the principal surface is no smaller than 0.8 mm² and no larger than 1.4 mm².

5. The quartz resonator blank according to claim 1, wherein
the resonance frequency is no lower than 48 MHz and no higher than 100 MHz,
the angle φ is no smaller than 8 degrees and no greater than 16 degrees, and
the area of the principal surface is no smaller than 2.0 mm² and no larger than 4.0 mm².

6. The quartz resonator blank according to claim 1, wherein
the resonance frequency is no lower than 48 MHz and no higher than 100 MHz,
the angle φ is no smaller than 9 degrees and no greater than 15.5 degrees, and
the area of the principal surface is no smaller than 1.4 mm² and no larger than 2.0 mm².

7. The quartz resonator blank according to claim 1, wherein
the angle φ is no smaller than 11.5 degrees and no greater than 12.5 degrees.

8. A quartz resonator comprising:
a package; and
the quartz resonator blank according to claim 1 to be housed in the package.

9. A quartz oscillator comprising:
the quartz resonator blank according to claim 1; and
a circuit section including at least a function of driving the quartz resonator blank.
